(19) United States
(12) Patent Application Publication
(10) Pub. No.: US 2025/0180889 A1
(43) Pub. Date: Jun. 5, 2025

(54) MEMS MICROMIRROR FOR ALLEVIATING OPTICAL PATH BLOCKAGE, AND PREPARATION METHOD THEREFOR

(71) Applicant: Xi'an Zhisensor Technologies Co.,Ltd., Xi'an (CN)

(72) Inventors: Xiumin SONG, Xi'an (CN); Wei HE, Xi'an (CN); Yong REN, Xi'an (CN)

(73) Assignee: Xi'an Zhisensor Technologies Co.,Ltd., Xi'an (CN)

(21) Appl. No.: 19/006,874

(22) Filed: Dec. 31, 2024

Related U.S. Application Data
(63) Continuation of application No. PCT/CN2023/104250, filed on Jun. 29, 2023.

(30) Foreign Application Priority Data
Jul. 26, 2022 (CN) 202210886743.8

(51) Int. Cl. G02B 26/08; B81B 3/00; B81C 1/00

(52) U.S. Cl. CPC G02B 26/0841; B81B 3/0021; B81C 1/00182; G02B 26/085; B81B 2201/042; B81B 2203/0154; B81C 2201/0187

(57) ABSTRACT

The present disclosure relates to a MEMS micromirror and a preparation method therefor, in particular to a MEMS micromirror for alleviating optical path blockage, and a preparation method therefor. According to the present disclosure, on the premise of not changing the conditions of a processing technology of a driver and a reflecting mirror in the MEMS micromirror and not affecting the normal operation of the MEMS micromirror, the fixed frame is optimized from the cutting design of a MEMS micromirror wafer, the fixed frame is transformed from a traditional closed frame to a non-closed fixed frame with a notch, while ensuring reliable support, in the large- angle scanning process, emitted light blocked by the traditional fixed frame can be directly emitted from the notch, thereby completely solving the problem of blocking light beams by the fixed frame itself of the MEMS micromirror in the scanning process.

### CROSS-REFERENCE TO RELATED APPLICATIONS

The application claims priority to Chinese patent application No. CN202210886743.8,filed on Jul. 26, 2022, the entire contents of which are incorporated herein by reference.

### TECHNICAL FIELD

The present disclosure relates to a MEMS micromirror and a preparation method therefor, in particular to a MEMS micromirror for alleviating the problem of optical path blockage caused by the own structure of the micromirror in the light beam scanning process, and a preparation method therefor.

### BACKGROUND

A MEMS micromirror is a micro electro mechanical system chip achieved based on a semiconductor micro-processing technology, and belongs to a microactuator, which can achieve accurate reflection and manipulation of laser beams, and is widely used in laser scanning, laser projection display, laser radar and optical communication fields. The MEMS micromirror mainly includes a closed fixed frame located around, and a movable structure located in the center of the fixed frame, the movable structure includes a plane reflecting mirror and a driver, and the plane reflecting mirror and the driver are connected to the fixed frame through a torsion shaft and suspended in the fixed frame. When a specific driving signal is applied, the plane reflecting mirror in the MEMS micromirror structure can be twisted around the shaft under driving of a driving structure. After a laser beam is projected onto a plane reflecting mirror surface, the direction of the reflected laser beam will also change along with the torsion of the reflecting mirror surface, thereby achieving laser scanning.

In the specific application scenario of the MEMS micromirror, an incident laser beam is generally projected onto the mirror surface perpendicular to the torsion shaft of the reflecting mirror and at an angle with the plane where the reflecting mirror is located. After the laser beam is reflected by the twisted mirror surface, the optical scanning angle range that is twice a mechanical torsion angle of the MEMS micromirror can be achieved. Due to the presence of the fixed frame around the MEMS micromirror, it is inevitable that when the scanning angle is large, part of emitted light will be blocked by the fixed frame, resulting in partial loss of laser energy, and even full blockage will limit the scanning angle range, as shown in FIG. 1, where 1 is a laser, 02 is a closed fixed frame, and 3 is a reflecting mirror. However, an anchor point of the plane reflecting mirror is located on the fixed frame of the MEMS micromirror, and the fixed frame is an indispensable important structure for achieving the function of the MEMS micromirror. Therefore, exploring a suitable way to solve the problem of optical path blockage caused by the fixed frame is of great significance for promoting the application of the MEMS micromirror and expanding the application scenarios of the MEMS micromirror.

At present, solutions are generally sought from the perspective of the design and micro-processing of the structure of a chip itself, and the reflecting mirror plane protruding from the fixed frame plane is one of the methods, but this solution requires more complex micro-processing technology and process to achieve, the processing cost is high, and a protruding structure does not facilitate subsequent processing and assembly operations of the MEMS micromirror. Expanding a distance between the reflecting mirror surface and the fixed frame is another solution, but this solution will increase the occupation area of a single chip, and also increase the cost. In addition to the cost factor, the above two solutions still have the problem of optical path blockage caused by the frame at a specific angle, and can not completely solve optical path blockage.

### SUMMARY

### Technical Problem

The present disclosure aims to provide a MEMS micromirror for alleviating optical path blockage and a preparation method therefor, to completely solve the problem of blocking light beams by a fixed frame itself of the MEMS micromirror in the scanning process at a low cost.

### Technical Solution

The present disclosure has the following concept:

In order to completely solve the problem of blocking the light beams by the fixed frame at a low cost, the present disclosure considers that on the premise of not changing the conditions of a processing technology of the driver and the reflecting mirror in the MEMS micromirror and not affecting the normal operation of the MEMS micromirror, the fixed frame is optimized from the cutting design of a MEMS micromirror wafer, the fixed frame is transformed from a traditional closed frame to a non-closed fixed frame with a notch, while ensuring reliable support, in the large-angle scanning process, emitted light blocked by the traditional fixed frame can be directly emitted from the notch, thereby completely solving the problem of blocking light beams by the fixed frame of the MEMS micromirror in the scanning process.

The technical solution of the present disclosure is to provide a MEMS micromirror for alleviating optical path blockage. The MEMS micromirror for alleviating optical path blockage includes a fixed frame and a movable structure located in a center of the fixed frame and connected to the fixed frame through a torsion beam, and a connection point between the torsion beam and the fixed frame is defined as an anchor point,

[symbol]

where, the fixed frame is formed in a cutting stage of a MEMS micromirror wafer, a notch is provided in the fixed frame, and the notch is located on a frame edge where no anchor point is located, so as to ensure that emitted light is directly emitted from the notch in a large-angle scanning process.

Further, the fixed frame is a rectangular, circular or other special-shaped frame. Therefore, the present disclosure is applicable to all MEMS micromirrors of different structural forms.

Further, in order to facilitate processing, a length of the notch and a length of another fixed frame edge where no anchor point is located are equal.

Further, the torsion beam and the movable structure may be located on the same side or different sides; and the movable structure includes a plane reflecting mirror and a driver, where the plane reflecting mirror and the driver may be located on the same side or different sides.

Further, a thickness of the movable structure may be the same as a thickness of the fixed frame, or may be less than the thickness of the fixed frame.

The present disclosure further provides a method for processing the above MEMS micromirror for alleviating optical path blockage. The method includes the following steps:
step 1, determining whether upper and lower surfaces of a movable structure in a to-be-processed MEMS micromirror are both partially coplanar with the fixed frame; if so, performing step 2; otherwise, attaching a side of a surface of the movable structure concaved into a plane of the fixed frame to a conventional scribing film, and performing step 3;
step 2, projecting a specific structure of a MEMS micromirror chip onto the scribing film, reserving adhesive layers of the scribing film corresponding to a non-closed fixed frame region and a wafer chip-free region to be used for fixing the chip, and peptizing adhesive layers corresponding to a movable structure region and a structure gap region until there is no viscosity at all to make the scribing film having a graphical adhesive layer; and aligning and attaching the MEMS micromirror wafer with the scribing film having the graphical adhesive layer.
step 3, cutting the chip into a fixed frame shape according to a designed scribing path, that is, providing the fixed frame with a notch in a frame edge where no anchor point is located.
step 4, expanding an interval of a MEMS micromirror chip array on the wafer by a film expanding technology until the chip is convenient to take, and forming a micromirror chip array with reasonable independent gaps; and
step 5, peptizing the entire cut and film-expanded wafer until a viscosity is reduced, and then taking out the chip.

Further, the scribing film in step 2 is an adhesive film with a viscosity capable of being adjusted by specific external applied conditions.

Further, the adhesive film is a UV peptizing film or heat peptizing film.

Further, in step 2, the adhesive layers of all projection regions except a fixed frame projection are peptized until there is no viscosity at all to make the scribing film having the graphical adhesive layer, and peptizing is achieved specifically by the following method:

[symbol] by a mask plate assisted lighting peptizing or gluing manner, or by an embossing and gluing manner; or by a mold assisted fixed-point heating and peptizing manner; or by attaching an additional graphical viscosity isolation film to the adhesive layer of the scribing film.

Further, in step 2, when aligning and attaching the MEMS micromirror wafer with the scribing film having the graphical adhesive layer, a front surface (reflecting mirror surface) of the MEMS micromirror may be attached to the scribing film having the graphical adhesive layer, or a back surface of the MEMS micromirror may be attached to the scribing film having the graphical adhesive layer.

The present disclosure further provides another method for processing the above MEMS micromirror for alleviating optical path blockage. The method includes the following steps:
step 1, determining whether upper and lower surfaces of a movable structure in a to-be- processed MEMS micromirror are both partially coplanar with the fixed frame; if so, performing step 2; otherwise, attaching a side of a surface of the movable structure concaved into a plane of the fixed frame to a conventional scribing film, and performing step 3;
step 2, making a graphical addition layer at a position of a non-closed fixed frame of a MEMS micromirror wafer by screen printing, to ensure good adhesion between screen printing paste and the non-closed fixed frame of the MEMS micromirror wafer and a smooth paste surface; attaching the MEMS micromirror wafer with the screen printing addition layer to a conventional scribing film, such that the MEMS micromirror is adhered to the conventional scribing film through the screen printing addition layer, and a part of the MEMS micromirror wafer corresponding to the movable structure of a chip will not make contact with and be attached to the conventional scribing film due to presence of the screen printing addition layer;
step 3, cutting the chip into a fixed frame shape according to a designed scribing path;
step 4, expanding an interval of a MEMS micromirror chip array on the wafer by a film diffusion process until the chip is convenient to take, and forming a micromirror chip array with reasonable independent gaps; and
step 5, peptizing the entire cut and film-expanded wafer until a viscosity is reduced, and then taking out the chip.

Further, in step 2, a thickness of the screen printing addition layer is 10-500 μm.

Further, in step 2, the screen printing addition layer is located on a surface with a larger printable area of the MEMS micromirror wafer.

### Beneficial Effects

The present disclosure has the following beneficial effects:
1. according to the present disclosure, from the cutting design of the MEMS micromirror wafer, on the premise of ensuring reliable support, the fixed frame is transformed from a traditional closed frame to a non-closed fixed frame with a notch, in the large-angle scanning process, emitted light blocked by the traditional fixed frame can be directly emitted from the notch, thereby completely solving the problem of blocking light beams by the fixed frame of the MEMS micromirror in the scanning process. At the same time, the fixed frame can be completed in the cutting stage of the wafer, thereby not affecting the processing technology of the driver and the reflecting mirror of the MEMS micromirror, and reducing the size of the chip to a certain extent, and the cost is low.
2. According to the present disclosure, through the specifically designed scribing film having the graphical adhesive layer or by adding the screen printing addition layer to the corresponding part of the frame of the MEMS micromirror wafer, the movable structure of the MEMS micromirror chip is prevented from being attached to the scribing film, conditions are created for subsequent chip cutting, film spreading and chip taking steps, and the technology is simple and reliable.

### BRIEF DESCRIPTION OF DRAWINGS

FIG. 1 is a schematic diagram of a scanning process of a MEMS micromirror with a traditional closed fixed frame;

in the figure: 1—laser, 02—closed fixed frame, and 3—reflecting mirror;

FIG. 2 is a schematic diagram of a scanning process of a MEMS micromirror according to an embodiment,

in the figure: 1—laser, 2—non-closed fixed frame, 3—reflecting mirror, and 14—emitted light;

FIG. 3a, FIG. 3b1, FIG. 3b2 and FIG. 3c is an overhead plane schematic diagram and cross-section schematic diagrams of a MEMS micromirror according to an embodiment, where FIG. 3a is an overhead plane schematic diagram of the MEMS micromirror; FIG. 3b1 is a cross-section schematic diagram along a Y line in FIG. 3a, where a torsion beam and a reflecting mirror are located on different sides; FIG. 3b2 is a cross-section schematic diagram along a Y line in FIG. 3a, where a torsion beam and a reflecting mirror are located on the same side; and FIG. 3c is a cross-section schematic diagram along an X line in FIG. 3a,

in the figure: 2—non-closed fixed frame, 3—reflecting mirror, 4—torsion beam, 5—anchor point, and 6—notch;

FIG. 4 is a schematic diagram of a scribing film having a graphical adhesive layer according to an embodiment;

FIG. 5 is a schematic diagram of design of a wafer cutting path according to Embodiment 1;

FIG. 6a, FIG. 6b1, FIG. 6b2 and FIG. 6c is an overhead plane schematic diagram and cross-section schematic diagrams of a MEMS micromirror with a traditional closed fixed frame, where FIG. 6a is an overhead plane schematic diagram of the MEMS micromirror; FIG. 6b1 is a cross-section schematic diagram along a Y line in FIG. 6a, where a torsion beam and a reflecting mirror are located on different sides; FIG. 6b2 is a cross-section schematic diagram along a Y line in FIG. 6a, where a torsion beam and a reflecting mirror are located on the same side; and FIG. 6c is a cross-section schematic diagram along an X line in FIG. 6a,

in the figure: 02—closed fixed frame, and 3—reflecting mirror;

FIG. 7 is a schematic diagram of a MEMS micromirror in which a movable structure suspended in a non-closed fixed frame is sunken into the fixed frame according to Embodiment 1,

in the figure: 2—non-closed fixed frame, 8—movable structure, and 9—concave surface;

FIG. 8 is a schematic diagram of a MEMS micromirror in which upper and lower surfaces of a movable structure suspended in a non-closed fixed frame are both partially coplanar with the fixed frame according to Embodiment 1,

in the figure: 2—non-closed fixed frame, 81—upper surface of movable structure, and 82—lower surface of movable structure;

FIG. 9a and FIG. 9b shows a graphical adhesive layer of a scribing film used in the MEMS micromirror corresponding to a fixed frame according to an embodiment, where FIG. 9a is the MEMS micromirror, and FIG. 9b is the graphical adhesive layer of the scribing film,

in the figure, 2—non-closed fixed frame, and 11—adhesive region;

FIG. 10 is a flow diagram of a method for making a scribing film having a graphical adhesive layer according to Embodiment 1;

FIG. 11a and FIG. 11b is schematic diagrams of a MEMS micromirror array and a graphical adhesive layer of a scribing film required thereby processed according to Embodiment 1, where FIG. 1la is the MEMS micromirror array, and FIG. 11b is the graphical adhesive layer of the scribing film required;

FIG. 12a is a cross-section schematic diagram along an X axis after a MEMS micromirror wafer adheres to a scribing film according to Embodiment 1, and

FIG. 12b is a cross-section schematic diagram along a Y axis after a MEMS micromirror wafer adheres to a scribing film according to Embodiment 1,

in the figures: 10—MEMS micromirror wafer, 11—adhesive region, and 12—peptizing region;

FIG. 13a, FIG. 13b and FIG. 13c is schematic diagrams of manufacturing screen printing addition layers on a MEMS micromirror wafer according to Embodiment 2, where FIG. 13a is an overhead plane schematic diagram of a MEMS micromirror; FIG. 13b is a cross-section schematic diagram along a Y line in FIG. 13a, where a torsion beam and a reflecting mirror are located on different sides; and FIG. 13c is a cross-section schematic diagram along an X line in FIG. 13a,

in the figure, 2—non-closed fixed frame, 3—reflecting mirror, 4—torsion beam, 5—anchor point, 6—notch, and 7—screen printing addition layer; and

FIG. 14 is a schematic diagram in which screen printing addition layers and a conventional scribing film adhere to a MEMS micromirror wafer according to Embodiment 2,

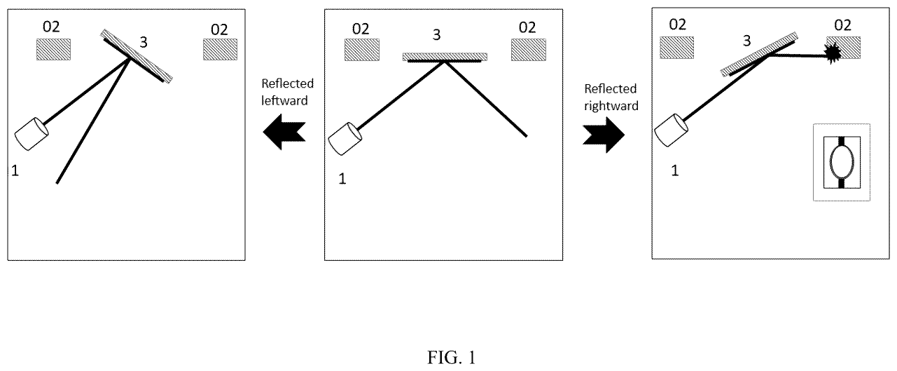

in the figure, 7—screen printing addition layer, 8—movable structure, and 13—conventional scribing film.

### DETAILED DESCRIPTION OF THE EMBODIMENTS

In order to make the above objectives, features and advantages of the present disclosure more clearly understood, specific implementations of the present disclosure are described in detail below with reference to the accompanying drawings of the specification. Obviously, described embodiments are only part of the embodiments of the present disclosure, rather than all the embodiments. Based on the embodiments of the present disclosure, all other embodiments obtained by those of ordinary skill in the art without any creative work shall fall within the scope of protection of the present disclosure.

In the following description, numerous specific details are set forth in order to provide a thorough understanding of the present disclosure. However, the present disclosure may be practiced otherwise than as specifically described herein. Persons skilled in the art may make similar generalizations without violating the connotation of the present disclosure, so that the present disclosure is not limited by the specific embodiments disclosed below.

The present disclosure envisages that if a MEMS micromirror which is easy to achieve from the process and can also completely and effectively solve the problem of optical path blockage can be developed in the cutting stage after processing a MEMS micromirror wafer, it will have greater application value and economic benefits.

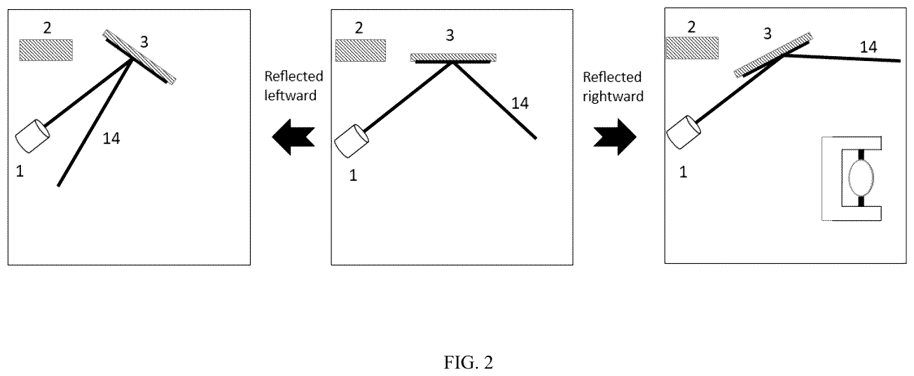

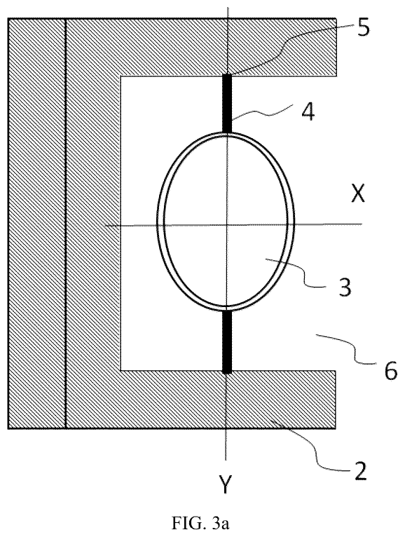

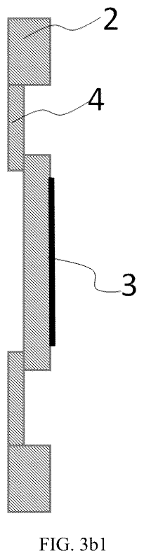

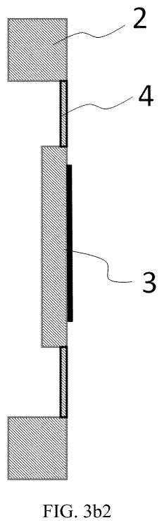

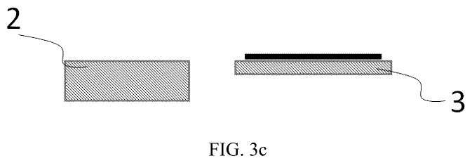

Based on the idea, the present disclosure starts from the cutting design of the MEMS micromirror wafer, and in this stage, a fixed frame is optimized, as shown in FIG. 2, the fixed frame is transformed from a traditional closed frame to a non-closed fixed frame with a notch, and the fixed frame can be defined as a non-closed fixed frame 2 or a C-shaped fixed frame. In the large-angle scanning process, emitted light 14 blocked by the traditional fixed frame and reflected by a reflecting mirror 3 can be directly emitted from the notch, thereby completely solving the problem of blocking light beams by the fixed frame of the MEMS micromirror in the scanning process. A size of the non-closed fixed frame 2 can be adjusted flexibly, which can still ensure the reliability of the support required by a MEMS chip frame, and can reduce the size of a chip to a certain extent. As shown in FIG. 3a, FIG. 3b1, FIG. 3b2 and FIG. 3c, in order to ensure the long-term stability of the relative position and function of a movable structure (including a reflecting mirror 3 and a driver) of the MEMS micromirror, as well as the operability of subsequent assembly of the MEMS micromirror, an anchor point 5 of each torsion beam 4 needs to be fixed on the same rigid support frame. Therefore, the notch 6 of the non-closed fixed frame 2 is provided in a frame edge where no anchor point 5 is located. The size of the notch 6 only needs to ensure that in the set large-angle scanning process, emitted light can be directly emitted from the notch 6 without being blocked by the fixed frame. The specific structural form of the fixed frame is not limited, for example, the fixed frame may be a rectangular, circular or other special-shaped frame.

However, since a reflecting mirror structure of a chip of the MEMS micromirror is suspended and movable, the whole wafer of the MEMS micromirror is cut into independent single chips, and a chip taking process is quite different from that of conventional semiconductor chips (such as IC chips and LED chips). Conventional grinding wheel mechanical cutting and laser cutting, because of larger influence of the water impact and particle pollution on the performance of the MEMS micromirror wafer, cannot be applied to processing of the MEMS micromirror wafer. At present, a main method that can be applied to cutting of the MEMS micromirror wafer is laser modified invisible cutting. In the cutting process, the MEMS micromirror wafer also has some special requirements for the use of film auxiliary materials, which not only need to meet the general requirements of fixing the wafer and a single chip after cutting, an expandable film, etc., but also need to meet the requirement of protecting the movable structure from adhesion damage of a film layer during chip taking. The current solution is mainly to perform optimization at the design end of the MEMS micromirror so as to use existing conventional films. Although the optimization at the design end can achieve the expected goal, this kind of solution needs to be at the cost of higher chip processing cost and more complex processing technological process.

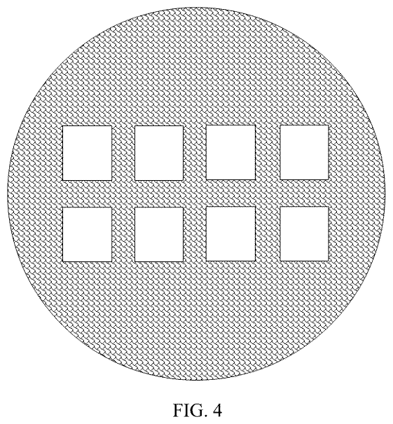

According to the present disclosure, in order to achieve three steps of smooth cutting, film expansion and chip taking of a MEMS micromirror chip with a non-closed fixed frame 2, as shown in FIG. 4, adhesive layers of a scribing film corresponding to a non-closed fixed frame region and a wafer chip-free region are reserved to be used for fixing the chip, and adhesive layers corresponding to a movable structure region and a structure gap region are peptized until there is no viscosity at all to make the scribing film having a graphical adhesive layer. In FIG. 4, a strip region is an adhesive layer corresponding to the non-closed fixed frame region and the wafer chip-free region of the wafer, and blank regions are adhesive-free regions, corresponding to the movable structure region and the structure gap region. In the cutting process, the movable structure is prevented from adhering to the scribing film. Screen printing addition layers may also be added to the non-closed fixed frame and the wafer chip-free region of the MEMS micromirror wafer, and then the MEMS micromirror wafer with the screen printing addition layers can be attached to a conventional scribing film, and then cut, which can also make the movable structure not adhere to the scribing film, thereby creating conditions for subsequent cutting, film expansion and chip taking steps of the chip, and the technology is simple and reliable.

With the assistance of the scribing film having the graphical adhesive layer or the screen printing addition layers, no matter whether the movable structure of the MEMS micromirror is coplanar with a front surface or back surface of the chip, or is not coplanar with the front surface and the back surface of the chip, since the movable structure never adheres to the scribing film, the film expansion link after cutting will not cause the movable microstructure to deform and damage with pulling up of the film, and finally, it is ensured that the cutting, film expansion and chip taking of the MEMS micromirror with the non-closed fixed frame can be successfully achieved.

The present disclosure is described in detail below in conjunction with the specific embodiments.

### Embodiment 1

The present embodiment takes an electromagnetic or electrostatic driven single-axis MEMS micromirror as an example for description:

As shown in FIG. 3a, FIG. 3b1, FIG. 3b2 and FIG. 3c, a main structure of a MEMS micromirror to be designed and processed in the present embodiment may be divided into a movable structure and a non-closed fixed frame 2. The movable structure includes a reflecting mirror 3, both sides of the reflecting mirror 3 are connected to the non-closed fixed frame 2 through torsion beams 4, and connection points between the torsion beams 4 and the non-closed fixed frame 2 are anchor points 5. The movable structure is suspended in the non-closed fixed frame 2. After the non-closed fixed frame 2 is fixed, the movable structure can perform reciprocating torsion around the torsion beams 4 under the condition of applying external driving force so as to achieve the function of the MEMS micromirror. The non-closed fixed frame 2 is a frame of a chip, is a fixed foundation of all other structures, and is a rectangular frame in which a notch 6 is provided. The notch 6 is located on a frame edge where no anchor point 5 is located, and a length of the notch and a length of another frame edge where no anchor point 5 is located are equal. In other embodiments, the length of the notch 6 can be adjusted according to the actual reflecting mirror surface size of the MEMS micromirror and the size of laser spots in the use scenario.

Thicknesses of the torsion beams and the movable structure may be the same as a thickness of the non-closed fixed frame 2, or may be less than the thickness of the fixed frame. If thinner than the fixed frame, the torsion beams and the movable structure can be thinned by wet etching or dry etching on the upper or lower surfaces.

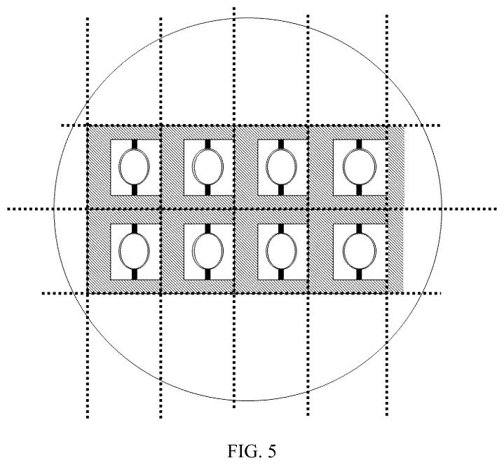

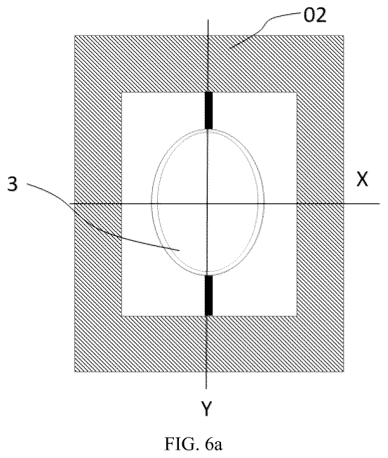

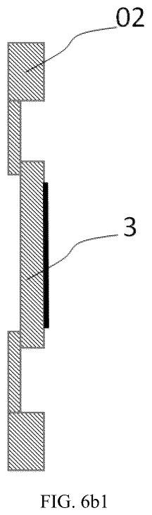

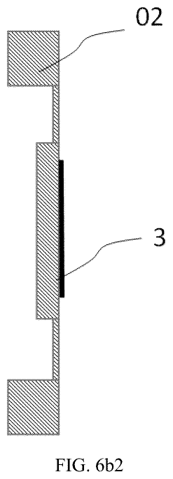

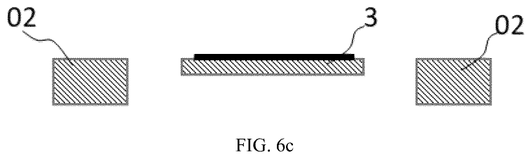

A cutting path of a MEMS micromirror wafer is designed in the appropriate X and Y axis directions, as shown in FIG. 5, black dotted lines in the figure are cutting paths, so that the MEMS micromirror chip is cut into a structure of the non-closed fixed frame 2, and the “closed” shape of the closed fixed frame 02 is shown in FIG. 6a, FIG. 6b1, FIG. 6b2 and FIG. 6c.

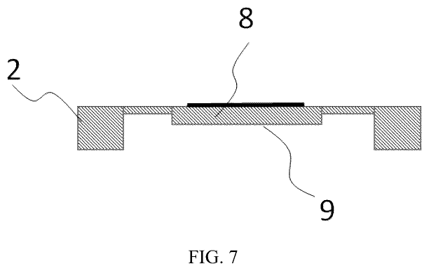

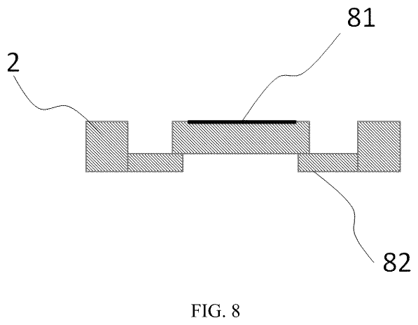

If at least one surface of the torsion beams 4 and the movable structure 8 suspended in the non-closed fixed frame 2 is not coplanar with the non-closed fixed frame 2, but is sunken into the non-closed fixed frame 2 (see a concave surface 9 in FIG. 7), a specially designed and processed graphical scribing film is not needed, only the concave surface of the structure needs to be attached to a conventional scribing film, at this time, the scribing film does not make contact with the concave surface 9 in the movable structure 8, and therefore, normal cutting, film expansion and chip taking can be performed. If an upper surface 81 of the torsion beams and the movable structure suspended in the non-closed fixed frame 2 and a lower surface 82 of the movable structure are both partially coplanar with the non-closed fixed frame 2 (see FIG. 8), a specially designed and processed graphical scribing film is needed for assistance, and cutting, film expansion and chip taking are completed according to the following steps.

A specific preparation method is as follows:

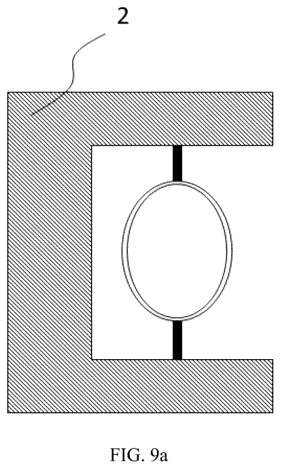

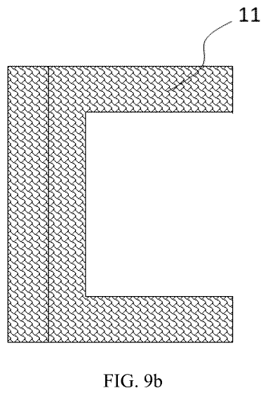

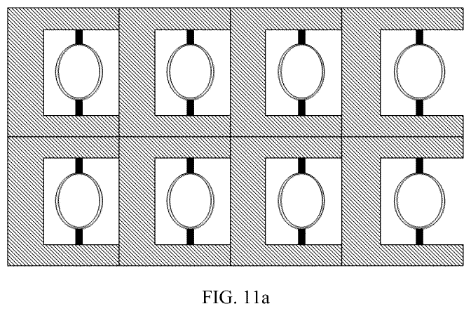

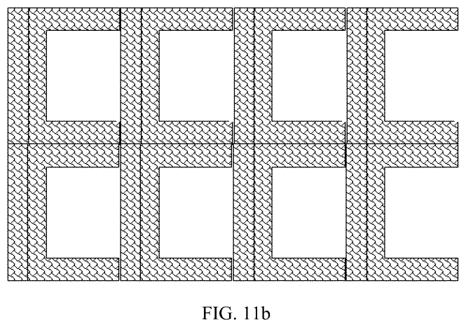

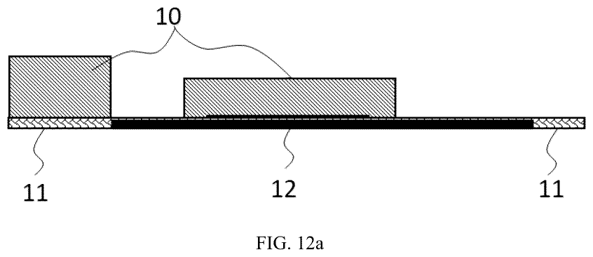

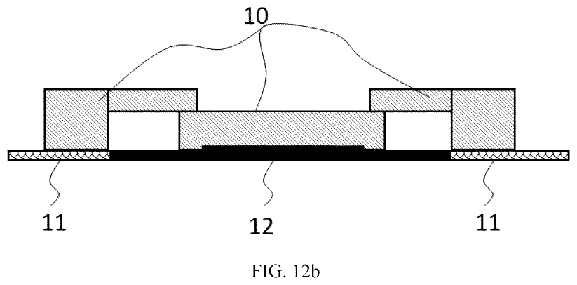

In conjunction with FIG. 9a and FIG. 9b to FIG. 12a and FIG. 12b, a scribing film is selected to be fixed on a scribing ring. The scribing film may be a UV peptizing film, a heat peptizing film, or other adhesive film with the viscosity capable of being adjusted by specific external applied conditions. A specific structure of a MEMS micromirror chip is projected onto the scribing film, adhesive layers of projection portions of the non-closed fixed frame 2 and a wafer chip-free region are reserved to be used for fixing the chip, and this region is defined as an adhesive region 11 (FIG. 9a, FIG. 9b and FIG. 11a, FIG. 11b); adhesive layers of projection portions of a movable structure region and a structure gap region are peptized until there is no viscosity at all, and this region is defined as a peptizing region 12 (FIG. 12a and FIG. 12b); and the scribing film having a graphical adhesive layer is manufactured.

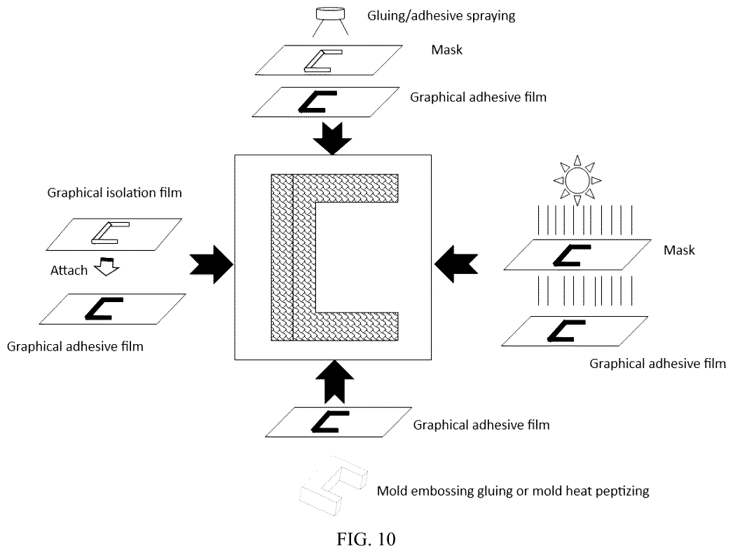

As shown in FIG. 10, patterning of the adhesive layer on the scribing film is achieved by a mask plate assisted lighting peptizing or gluing manner, or by an embossing and gluing manner; or by a fixed-point heating and peptizing manner; or by attaching an additional graphical viscosity isolation film to the adhesive layer of the scribing film.

As shown in FIG. 12a and FIG. 12b, the MEMS micromirror wafer 10 is aligned and attached with the scribing film having the graphical adhesive layer, the alignment accuracy is determined by the structural size of the MEMS micromirror chip and the dimensional accuracy of the graphical adhesive layer, and the general accuracy requirement is not high and about +/−0.2 mm. During attaching, a front surface (reflecting mirror surface) of the MEMS micromirror may be attached to the scribing film, or a back surface of the MEMS micromirror may be attached to the scribing film, there is no special requirement, and an appropriate fixture can be selected and designed according to the actual needs to assist the alignment of the film.

After the MEMS micromirror wafer 10 is attached and fixed on the scribing film, the chip is cut into a border in a similar “C” shape according to the designed scribing path.

The film is expanded after cutting until an interval of a MEMS micromirror chip array on the wafer is expanded for facilitating chip taking, and a micromirror chip array with reasonable independent gaps is formed.

Before chip taking, the entire cut and film-expanded wafer is peptized until the viscosity is obviously reduced, and the reduction degree is set according to the actual situation.

### Embodiment 2

The present embodiment takes an electromagnetic or electrostatic driven single-axis MEMS micromirror as an example:

A main structure of a MEMS micromirror to be designed and processed in the present embodiment may be divided into a movable structure and a fixed frame. The movable structure includes a reflecting mirror 3, both sides of the reflecting mirror 3 are connected to the fixed frame through torsion beams 4, and connection points between the torsion beams 4 and the fixed frame are anchor points 5. The movable structure is suspended in the fixed frame. After the fixed frame is fixed, the movable structure can perform reciprocating torsion around the torsion beams 4 under the condition of applying external driving force so as to achieve the function of the MEMS micromirror. The fixed frame is a frame of a chip, is a fixed foundation of all other structures, and is a rectangular frame in which a notch 6 is provided. The notch 6 is located on a frame edge where no anchor point 5 is located, and a length of the notch and a length of another frame edge where no anchor point 5 is located are equal. In other embodiments, the length of the notch 6 can be adjusted according to the actual reflecting mirror 3 surface size of the MEMS micromirror and the size of laser spots in the use scenario.

Thicknesses of the torsion beams and the movable structure may be the same as a thickness of the fixed frame, or may be less than the thickness of the fixed frame. If thinner than the fixed frame, the torsion beams and the movable structure can be thinned by wet etching or dry etching on the upper or lower surfaces.

A cutting path of a MEMS micromirror wafer is designed in the appropriate X and Y axis directions, so that the MEMS micromirror chip is cut into a “C” shape of an opening fixed frame, rather than a “closed” shape of the non-closed fixed frame.

If at least one surface of the torsion beams 4 and the movable structure 8 suspended in the non-closed fixed frame 2 is not coplanar with the non-closed fixed frame 2, but is sunken into the non-closed fixed frame 2 (see a concave surface 9 in FIG. 7), screen printing addition layers 7 do not need to be manufactured, only the concave surface of the structure needs to be attached to a conventional scribing film, and normal cutting, film expansion and chip taking can be performed. If an upper surface 81 of the torsion beams and the movable structure suspended in the non-closed fixed frame 2 and a lower surface 82 of the movable structure are both partially coplanar with the non-closed fixed frame 2 (see FIG. 8), addition layers need to be manufactured on the wafer by screen printing, and then cutting, film expansion and chip taking are completed by the conventional scribing film according to the following steps.

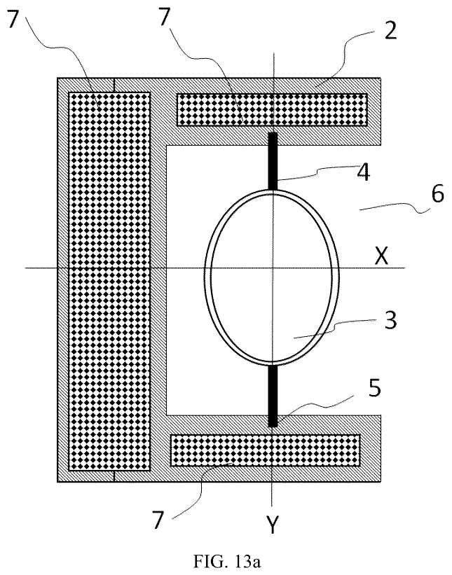

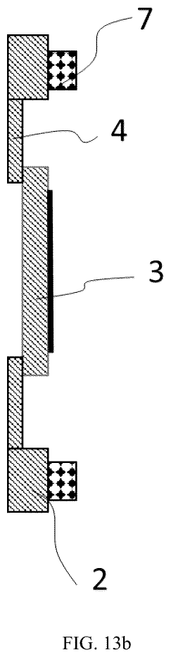

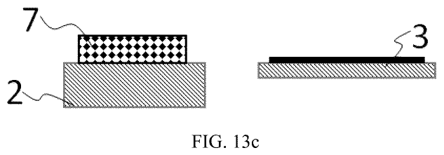

As shown in FIG. 13a, FIG. 13b and FIG. 13c, a screen printing paste is selected, graphical screen printing addition layers 7 are manufactured on the non-closed fixed frame 2 of the MEMS micromirror wafer by screen printing and have the thickness of 10-100 μm, and it is ensured that good adhesion is formed between the screen printing paste and the non-closed fixed frame 2 of the MEMS micromirror wafer and the paste surface is smooth. Further, a screen printing surface may be any surface of the MEMS micromirror wafer, optionally, a surface with a larger printable area.

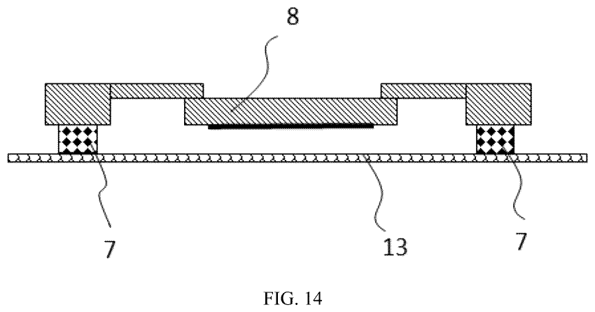

As shown in FIG. 14, the MEMS micromirror wafer with the screen printing addition layers 7 is attached to a conventional scribing film 13, such that the screen printing addition layers 7 adhere to the conventional scribing film 13, and the movable structure 8 of the chip will not make contact with and be attached to the conventional scribing film 13 due to presence of the screen printing addition layers 7.

After the MEMS micromirror wafer is attached and fixed on the conventional scribing film 13, the chip is cut into a frame in a similar “C” shape according to the designed scribing path, rather than in a conventional “closed” shape.

The film is expanded after cutting until an interval of a MEMS micromirror chip array on the wafer is expanded for facilitating chip taking, and a micromirror chip array with reasonable independent gaps is formed.

Before chip taking, the entire cut and film-expanded wafer is peptized until the viscosity is obviously reduced, and the reduction degree is set according to the actual situation.

What is claimed is:

1. A MEMS micromirror for alleviating optical path blockage, comprising a fixed frame and a movable structure (8) located in a center of the fixed frame and connected to the fixed frame through a torsion beam (4), a connection point between the torsion beam (4) and the fixed frame being defined as an anchor point (5);
wherein, the fixed frame is formed in a cutting stage of a MEMS micromirror wafer, a notch (6) is provided in the fixed frame, and the notch (6) is located on a frame edge where no anchor point is located, so as to ensure that emitted light is directly emitted from the notch (6) in a large-angle scanning process.

2. The MEMS micromirror for alleviating optical path blockage according to claim 1, wherein the fixed frame is a rectangular, circular or other special-shaped frame.

3. The MEMS micromirror for alleviating optical path blockage according to claim 2, wherein a length of the notch (6) and a length of another frame edge where no anchor point is located are equal.

4. The MEMS micromirror for alleviating optical path blockage according to claim 3, wherein the torsion beam (4) and the movable structure (8) are located on the same side or different sides; and the movable structure (8) comprises a plane reflecting mirror (3) and a driver, and the plane reflecting mirror (3) and the driver are located on the same side or different sides.

5. The MEMS micromirror for alleviating optical path blockage according to claim 4, wherein a thickness of the movable structure (8) is less than or equal to a thickness of the fixed frame.

6. A method for processing a MEMS micromirror for alleviating optical path blockage according to claim 1, comprising the following steps:
step 1, determining whether upper and lower surfaces of a movable structure (8) in a to-be-processed MEMS micromirror are both partially coplanar with the fixed frame, if so, performing step 2; otherwise, attaching a side of a surface of the movable structure (8) concaved into a plane of the fixed frame to a conventional scribing film (13), and performing step 3;
step 2, projecting a specific structure of a MEMS micromirror chip onto the scribing film, reserving adhesive layers of the scribing film corresponding to a non-closed fixed frame region and a wafer chip-free region to be used for fixing the chip, and peptizing adhesive layers corresponding to a movable structure region and a structure gap region until there is no viscosity at all to make the scribing film having a graphical adhesive layer; and aligning and attaching the MEMS micromirror wafer with the scribing film having the graphical adhesive layer;
step 3, cutting the chip into a fixed frame shape according to a designed scribing path;
step 4, expanding an interval of a MEMS micromirror chip array on the wafer by a film expanding technology until the chip is convenient to take, and forming a micromirror chip array with reasonable independent gaps; and
step 5, peptizing the entire cut and film-expanded wafer until a viscosity is reduced, and then taking out the chip.

7. The method for processing the MEMS micromirror for alleviating optical path blockage according to claim 6, wherein the scribing film in step 2 is an adhesive film with a viscosity capable of being adjusted by specific external applied conditions.

8. The method for processing the MEMS micromirror for alleviating optical path blockage according to claim 7, wherein the adhesive film is a UV peptizing film or heat peptizing film.

9. The method for processing the MEMS micromirror for alleviating optical path blockage according to claim 8, wherein in step 2, the adhesive layers of all projection regions except a fixed frame projection are peptized until there is no viscosity at all to make the scribing film having the graphical adhesive layer, and peptizing is achieved specifically by the following method:
peptizing by mask plate assisted lighting;
or by an embossing and gluing manner;
or by a mold assisted fixed-point heating and peptizing manner;
or by attaching an additional graphical viscosity isolation film to the adhesive layer of the scribing film.

10. The method for processing the MEMS micromirror for alleviating optical path blockage according to claim 9, wherein in step 2, when aligning and attaching the MEMS micromirror wafer with the scribing film having the graphical adhesive layer, a front surface of the MEMS micromirror is attached to the scribing film having the graphical adhesive layer, or a back surface of the MEMS micromirror is attached to the scribing film having the graphical adhesive layer.

11. A method for processing a MEMS micromirror for alleviating optical path blockage according to claim 1, comprising the following steps:
step 1, determining whether upper and lower surfaces of a movable structure (8) in a to-be-processed MEMS micromirror are both partially coplanar with the fixed frame; if so, performing step 2; otherwise, attaching a side of a surface of the movable structure (8) concaved into a plane of the fixed frame to a conventional scribing film (13), and performing step 3;
step 2, making a graphical addition layer on a non-closed fixed frame region and a wafer chip-free region of a MEMS micromirror wafer by screen printing; attaching the MEMS micromirror wafer with the screen printing addition layer (7) to a conventional scribing film (13), such that a MEMS micromirror chip adheres to the conventional scribing film (13) through the screen printing addition layer (7), and a part of the MEMS micromirror wafer corresponding to the movable structure (8) of the chip will not make contact with and be attached to the conventional scribing film (13) due to presence of the screen printing addition layer (7);
step 3, cutting the chip into a fixed frame shape according to a designed scribing path;
step 4, expanding an interval of a MEMS micromirror chip array on the wafer by a film expanding technology until the chip is convenient to take, and forming a micromirror chip array with reasonable independent gaps; and
step 5, peptizing the entire cut and film-expanded wafer until a viscosity is reduced, and then taking out the chip.

12. The method for processing the MEMS micromirror for alleviating optical path blockage according to claim 11, wherein in step 2, a thickness of the screen printing addition layer (7) is 10-500 μm.

13. The method for processing the MEMS micromirror for alleviating optical path blockage according to claim 12, wherein in step 2, the screen printing addition layer (7) is located on a surface with a larger printable area of the MEMS micromirror wafer.
